(19) United States
(12) Patent Application Publication
(10) Pub. No.: US 2026/0239965 A1
(43) Pub. Date: Aug. 13, 2026

(54) Two-piece lid assembly for liquid metal thermal interface material containment

(71) Applicant: Marvell Asia Pte Ltd, Singapore (SG)

(72) Inventors: Assaad El Helou, Los Angeles, CA (US); Pushkraj Tumne, Agoura Hills, CA (US); Dwayne R. Shirley, Valley Glen, CA (US)

(21) Appl. No.: 19/534,838

(22) Filed: Feb. 10, 2026

Related U.S. Application Data
(60) Provisional application No. 63/757,254, filed on Feb. 11, 2025.

(51) Int. Cl. H10W 40/20; H10W 40/00; H10W 42/00

(52) U.S. Cl. CPC H10W 40/242; H10W 40/01; H10W 42/121

(57) ABSTRACT

An electronic device includes: (a) an integrated circuit (IC) die mounted on a substrate; (b) a stiffener, on the substrate, having a bottom surface facing the substrate and an opening aligned with the IC die; (c) a liquid metal (LM) thermal interface material (TIM) on the upper surface of the IC die, and facing the opening; and (d) a lid on the stiffener. The lid includes (i) a protrusion extending from a lower surface toward the IC die, aligned with the opening and configured to contact the LM TIM, and (ii) channels in the lower surface surrounding the protrusion. When the lid is placed on the stiffener, the protrusion displaces the LM TIM to fill the volume between the lid and the IC die, and the channels receive LM TIM overflow.

### CROSS-REFERENCE TO RELATED APPLICATIONS

This application claims the benefit of U.S. Provisional Patent Application 63/757,254, filed February 11, 2025, whose disclosure is incorporated herein by reference.

### FIELD OF THE DISCLOSURE

The present invention relates generally to packaging of electronic devices, and particularly to improved methods and systems for containing liquid metal thermal interface material in semiconductor packages using a two-piece lid assembly.

### BACKGROUND

Liquid metal thermal interface materials offer high thermal conductivity for heat dissipation in integrated circuit packages, but their low viscosity and high surface tension present challenges related to containment, coverage uniformity, and protection from oxidation during package assembly and operation.

The description above is presented as a general overview of related art in this field and should not be construed as an admission that any of the information it contains constitutes prior art against the present patent application.

### SUMMARY

An embodiment of the present invention that is described herein provides an electronic device, including (a) an integrated circuit (IC) die mounted on a substrate, (b) a stiffener disposed on the substrate, the stiffener includes a bottom surface facing at least the substrate, and an opening aligned with at least part of the IC die, (c) a liquid metal thermal interface material (TIM) disposed on an upper surface of the IC die facing the opening, and (d) a lid disposed on the stiffener. The lid includes (I) a protrusion extending from a lower surface of the lid toward the IC die, the protrusion is aligned with the opening and configured to contact the liquid metal TIM, and (II) one or more channels formed in the lower surface of the lid and shaped to at least partially surround the protrusion. In response to placing the lid on the stiffener, the protrusion is configured to displace the liquid metal TIM to fill a volume defined between the lid and the upper surface of the IC die, and the one or more channels are configured to receive overflow of the liquid metal TIM from the volume.

In some embodiments, an edge of the stiffener defining the opening includes a first surface facing the IC die and a second surface sloped and configured to direct the overflow of the liquid metal TIM from the volume toward the one or more channels. In other embodiments, the electronic device further includes a seal ring disposed between (i) the first surface at the edge of the stiffener, and (ii) a die edge at the upper surface of the IC die, the seal ring is configured to laterally bound the liquid metal TIM within the volume. In yet other embodiments, the seal ring includes a thermally conductive adhesive.

In some embodiments, an amount of the liquid metal TIM exceeds a capacity of the volume defined between the lid and the upper surface of the IC die, and the one or more channels provide a buffer volume to contain the overflow. In other embodiments, the one or more channels include a first channel connected all around the protrusion. In yet other embodiments, the one or more channels further include a second channel disposed outward of the first channel.

In some embodiments, the one or more channels include a plurality of discrete channels disposed adjacent to respective sides of the protrusion. In other embodiments, the plurality of discrete channels includes two parallel channels disposed adjacent to each side of the protrusion. In yet other embodiments, the lid is configured to provide a hermetic seal to protect the liquid metal TIM from oxidation.

In some embodiments, the one or more channels are configured to contain residual liquid metal TIM, such that, in response to warping or flexing of the electronic device, the residual liquid metal TIM is configured to flow back into the volume. In other embodiments, the protrusion is configured to reduce a thickness of the liquid metal TIM between the lid and the upper surface of the IC die.

There is additionally provided, in accordance with an embodiment of the present invention, a method for fabricating an electronic device, the method including mounting an integrated circuit (IC) die on a substrate. A stiffener is disposed (e.g., mounted) on the substrate, the stiffener includes: (i) a bottom surface facing at least the substrate, and (ii) an opening aligned with at least part of the IC die. A liquid metal thermal interface material (TIM) is dispensed on an upper surface of the IC die facing the opening. A lid is placed (e.g., mounted) on the stiffener, the lid includes: (i) a protrusion extending from a lower surface of the lid toward the IC die, and the protrusion is aligned with the opening and configured to contact the liquid metal TIM, and (ii) one or more channels formed in the lower surface of the lid and shaped to at least partially surround the protrusion. Placing the lid on the stiffener includes displacing the liquid metal TIM via the protrusion to fill a volume defined between the lid and the upper surface of the IC die, and directing overflow of the liquid metal TIM from the volume into the one or more channels.

There is further provided, in accordance with an embodiment of the present invention, an electronic device, including an integrated circuit (IC) die mounted on a substrate, means for stiffening disposed on the substrate and having an opening aligned with at least part of the IC die, a liquid metal thermal interface material (TIM) disposed on an upper surface of the IC die facing the opening, and means for covering disposed on the means for stiffening. The means for covering include (a) means for contacting extending toward the IC die, the means for contacting is aligned with the opening and configured to contact the liquid metal TIM, and means for containing overflow, shaped to at least partially surround the means for contacting. In response to placing the means for covering on the means for stiffening, the means for contacting is configured to displace the liquid metal TIM to fill a volume defined between the means for covering and the upper surface of the IC die, and the means for containing overflow is configured to receive overflow of the liquid metal TIM from the volume.

The present disclosure will be more fully understood from the following detailed description of the embodiments thereof, taken together with the drawings in which:

### BRIEF DESCRIPTION OF THE DRAWINGS

FIG. 1 is a schematic cross-sectional view of an electronic device with a lid assembly and liquid metal thermal interface material, in accordance with an embodiment that is described herein;

FIG. 2 is a schematic bottom view of the lid of FIG. 1 showing a first configuration of overflow channels, in accordance with an embodiment that is described herein;

FIG. 3 is a schematic bottom view of the lid of FIG. 1 showing a second configuration of overflow channels, in accordance with another embodiment that is described herein;

FIG. 4 is a series of schematic cross-sectional views showing an assembly sequence of the electronic device of FIG. 1 with a two-piece lid construction, in accordance with an embodiment that is described herein; and

FIG. 5 is a flowchart of a method for assembling the electronic device of FIG. 1, in accordance with an embodiment that is described herein.

### DETAILED DESCRIPTION OF EMBODIMENTS

Liquid metal thermal interface materials (TIMs) offer high thermal conductivity at interfaces between silicon dies and heatspreader or lid solutions in IC packages. Liquid metal remains liquid at room temperature and provides flowability to conform to interfaces. Liquid metal can be displaced to a bond line thickness below 20 μm, a thickness not otherwise achievable with other thermal interface materials. Unlike polymer thermal interface materials with high filler content or solid solder thermal interface materials, liquid metal does not suffer from cracking, delamination, voiding, or high stress issues. However, liquid metal thermal interface materials have high surface tension and low viscosity. These properties make liquid metal difficult to contain and control, leading to workability and containment concerns at the package level. One issue is that liquid metal tends to run off during lid placement, resulting in low thermal interface material coverage across the die and a low conductance thermal interface. Another issue is that leakage of liquid metal can cause electrical shorts if liquid metal contacts other components near the die, such as surface mount device components on the substrate top face. In addition, liquid metal is highly reactive to humidity and oxidizes if not protected. Oxidation results in reliability issues when the package is subjected to high temperature and high humidity testing conditions, such as highly accelerated stress testing (HAST), which is part of package qualification testing.

Existing solutions to contain liquid metal have limitations. One solution uses foam material to contain liquid metal around the die area. This foam solution is used at the system level but is not applicable at the package level because foam cannot resist peak reflow temperatures in excess of 250°C. Another solution protects components closest to the silicon die using a UV curable coating. However, UV curable coatings do not solve liquid metal spillage that leads to low die coverage and poor thermal conductance at the interface. UV curable coatings also do not address liquid metal oxidation. Another solution uses a gasket ring around the die to control overflow. However, liquid metal leaks from the gasket when the package warps during temperature cycling, and liquid metal gradually empties from between the silicon die and the lid.

Embodiments of the present disclosure that are described herein provide techniques for improving heat dissipation from one or more integrated circuit (IC) dies assembled in a package. In some embodiments, an electronic device comprises a two-piece lid assembly that addresses containment, coverage, and protection of liquid metal thermal interface material (TIM). The two-piece lid assembly comprises a stiffener and a lid. The stiffener is disposed on a substrate and surrounds an integrated circuit (IC) die mounted on the substrate. The lid is positioned over the stiffener and the IC die.

In some embodiments, the stiffener is shaped to isolate a TIM region from a top surface of the substrate. The stiffener comprises an opening aligned with the IC die, and the stiffener extends over portions of the substrate surrounding the IC die. An edge of the stiffener defining the opening comprises a sloped surface configured to direct overflow of the liquid metal TIM toward the overflow containment channels. The stiffener is coupled to the substrate by an adhesive layer. In some embodiments, the stiffener is configured to prevent liquid metal TIM from contacting components on the substrate top surface, thereby avoiding electrical shorts that could otherwise occur if liquid metal were to leak onto surface-mounted device (SMD) components.

In some embodiments, the lid comprises a protrusion that extends toward the IC die. The protrusion reduces the thickness of the liquid metal TIM disposed between the IC die and the lid, thereby improving thermal conductance across the interface. The lid further comprises overflow containment channels formed in the lower surface of the lid. The overflow containment channels are configured to receive and contain excess liquid metal TIM that overflows from an interface between the IC die and the protrusion.

In some embodiments, the overflow containment channels comprise an inner overflow channel and an outer overflow channel. The inner overflow channel is positioned closer to the protrusion, and the outer overflow channel is positioned outward from the inner overflow channel. In some embodiments, the overflow containment channels form continuous peripheral channels that extend around a perimeter of the protrusion. The continuous peripheral configuration allows overflow liquid metal to distribute evenly around the perimeter rather than favoring one side over another.

In some embodiments, a seal ring is disposed between the stiffener and the IC die. The seal ring is positioned on an edge of the IC die and configured to provide lateral bounding of the liquid metal TIM. The seal ring comprises a thermally conductive adhesive material. In some embodiments, the seal ring provides a hermetic seal that protects the liquid metal TIM from humidity and oxidation. The hermetic seal enables the electronic device to withstand high temperature and high humidity testing conditions.

In some embodiments, the liquid metal TIM is dispensed in an amount that exceeds the volume capacity between the IC die and the protrusion (e.g., over 100% up to about 120%). When the lid is placed on the stiffener, the protrusion displaces the liquid metal TIM to spread across the upper surface of the IC die, achieving full die coverage. Excess liquid metal TIM flows into the overflow containment channels. As used herein, the term "displace" (and grammatical variants such as "displaces" "displacing" and "to displace"), when referring to liquid metal thermal interface material (LM TIM), means to mechanically act on the LM TIM, by applying contact pressure and/or shear via relative movement of adjacent components during assembly (for example, bringing a lid and a stiffener together and seating a protrusion), so as to press, move, distribute, and arrange the LM TIM to flow and spread into and substantially fill an intended interface volume and, where excess LM TIM is present, to direct such excess LM TIM to overflow into one or more channels or recesses.

In some embodiments, the liquid metal TIM contained within the overflow containment channels serves as a reservoir. When the electronic device experiences package warping or flexing due to thermal or mechanical loading, liquid metal TIM from the reservoir flows back into a cavity between the IC die and the protrusion. The reservoir function reduces voiding and maintains thermal performance during operational cycling.

In some embodiments, the lid is coupled to the stiffener by an adhesive layer. The adhesive layer is subjected to a thermal process to form a hermetic seal between the lid and the stiffener. The hermetic seal, in combination with the seal ring, encapsulates the liquid metal TIM and protects the liquid metal TIM from environmental exposure.

The description above is presented as a general overview of embodiments of the present disclosure, which are described in detail herein.

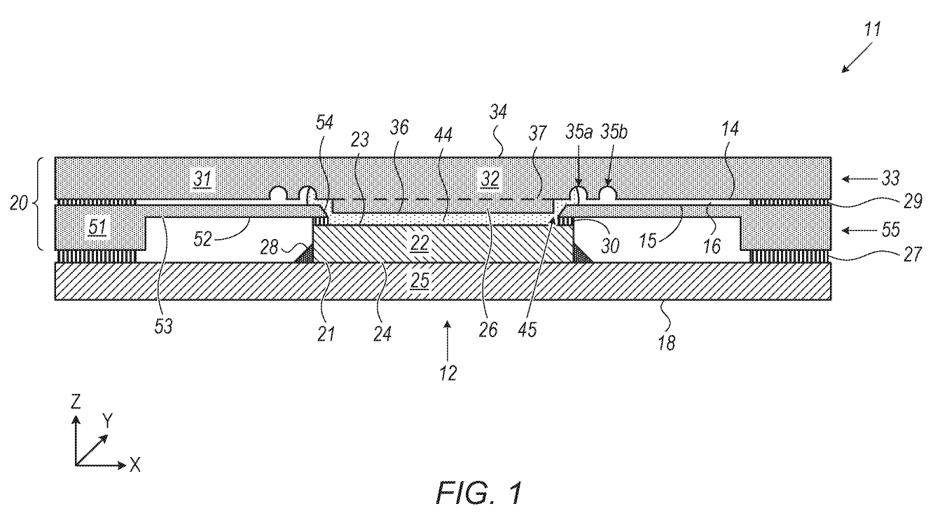

FIG. 1 is a cross-sectional view of an electronic device 11 with a lid assembly 20 and liquid metal (LM) thermal interface material (TIM) 44, in accordance with an embodiment that is described herein. In some embodiments, electronic device 11 comprises a substrate 25 having an upper surface 21 and a lower surface 18. Substrate 25 may comprise any suitable substrate, such as but not limited to a circuit board, a laminate, or an interposer. In some embodiments, an Integrated Circuit (IC) die 22 is mounted on upper surface 21 of substrate 25. IC die 22 comprises any suitable type of IC, such as a processor, a memory device, a stack of memory devices, an Application-Specific Integrated Circuits (ASICs) or Field-Programmable Gate Arrays (FPGAs). IC die 22 has an upper surface 23, and electronic device 11 comprises terminals 24 (such as bumps or hybrid bonding) providing electrical connection between IC die 22 and substrate 25, and filling material 28 disposed between IC die 22 and substrate 25 and configured to provide mechanical support to prevent damage to terminals 24. In other embodiments, electronic device 11 may comprise multiple IC dies, chiplets, and/or IC modules, for example in a multichip module (MCM) configuration and/or in 2.5D, 3.5D, or other multi-die package architectures in which multiple dies or modules are disposed on an interposer.

In some embodiments, electronic device 11 comprises a stiffener 55 disposed on substrate 25 and surrounds IC die 22. Stiffener 55 comprises a section 51 coupled to surface 21 of substrate 25, and a section 52 defining an opening 12 described herein. In some embodiments, stiffener 55 has an upper surface 15 and a lower surface 53. Moreover, stiffener 55 has a sloped edge 54 that defines the edge of opening 12 in stiffener 55. In some embodiments, opening 12 is aligned with at least a portion of IC die 22. Sloped edge 54 provides a transition between stiffener upper surface 15 and opening 12, which is facing IC die 22. In some embodiments, stiffener 55 has an overhang that extends over the edge of IC die 22 to define a region intended to receive a LM TIM 44 and isolate the TIM region from upper surface 21 of substrate 25.

In some embodiments, an adhesive layer 27 is disposed between and configured to couple stiffener 55 to substrate 25. Adhesive layer 27 comprises a stiffener attach adhesive, which in some embodiments comprises an epoxy-based, silicone-based, or acrylic-based thermally conductive adhesive. In some embodiments, the stiffener attachment adhesive may be composed of the same material as a seal ring adhesive. In other embodiments, the stiffener attach adhesive can be a different material from the seal ring adhesive.

In some embodiments, a seal ring 30 is positioned between stiffener 55 and IC die 22. Seal ring 30 is disposed on an edge of IC die 22. Seal ring 30 is configured to isolate the TIM region from upper surface substrate 21 and to prevent liquid metal leakage onto substrate 25. In some embodiments, seal ring 30 comprises a thermally conductive adhesive with fillers. Seal ring 30 can have a width of less than half a millimeter, such as between about 300 microns and 400 microns, on the edge of IC die 22. In some embodiments, the width of seal ring 30 is further reduced to increase the area of the interface occupied by liquid metal TIM 44, without compromising the seal's ability to contain LM TIM 44 and prevent its exposure to humidity, gases (which can result in oxidation), or contaminants.

In some embodiments, a lid 33 is positioned over stiffener 55 and IC die 22. Lid 33 has an upper surface 34, a lower surface 14, a peripheral section 31, and a central section 32. In the present example, section 31 is positioned over and coupled to stiffener section 51 using an adhesive layer 29 disposed therebetween.

In some embodiments, section 32 comprises a protrusion 26, which extends from lid 33 toward IC die 22. Protrusion 26 has a protrusion lower surface 36 that faces upper surface 23 of IC die 22. In some embodiments, protrusion 26 is configured to reduce the thickness of TIM 44 disposed between the IC die upper surface 23 and the protrusion lower surface 36. In some embodiments, the reduced thickness improves thermal conductance between IC die 22 and lid 33. The liquid metal TIM 44 may achieve a bond line thickness less than about 20 micrometers due to the flowability of the liquid metal TIM 44 when lid 33 is placed on stiffener 55.

In some embodiments, lid assembly 20 of electronic device 11 has an opening 45 defined by sloped edges 54 and protrusion 26 between stiffener 55 and lid 33. In some embodiments, sloped edge 54 is configured to direct overflow of the liquid metal TIM 44 toward channels 35a and 35b formed in the lower surface 14 of lid 33.

In some embodiments, an inner overflow channel 35a and an outer overflow channel 35b may be formed in lower surface 14 of lid 33. The inner overflow channel 35a and the outer overflow channel 35b are configured to contain excess liquid metal TIM 44 that overflows from the interface between IC die 22 and protrusion 26. A virtual line 37 indicates the area of protrusion 26 that extends outside lower surface 14 of lid 33. In some embodiments, a gap 16, between surfaces 14 and 15 may be used to accommodate additional adhesive material for improved sealing (for example, hermetic sealing) and/or to accommodate placement of a thin barrier layer configured to reduce oxidation of the TIM 44. In other embodiments, gap 16 may be formed to contain additional excess TIM 44.

In some embodiments, adhesive layer 29 is configured to form a hermetic seal that protects the liquid metal TIM 44 from humidity and oxidation during high temperature and high humidity conditions during testing as well as when electronic device 11 operates as a component of an electronic system. In some embodiments, seal ring 30 may have a width between about 300 microns and 400 microns positioned at the edge of IC die 22 to contain the liquid metal TIM 44 on top of the IC die 22 and within a volume of the TIM region defined between surface 36 of the lid and the upper surface 23 of IC die 22.

This particular configuration of electronic device 11 is shown by way of example, in order to illustrate certain problems that are addressed by embodiments of the present invention and to demonstrate the application of these embodiments in enhancing the performance of such a device. Embodiments of the present invention, however, are by no means limited to this specific sort of example electronic device, and the principles described herein may similarly be applied to other sorts of electronic devices.

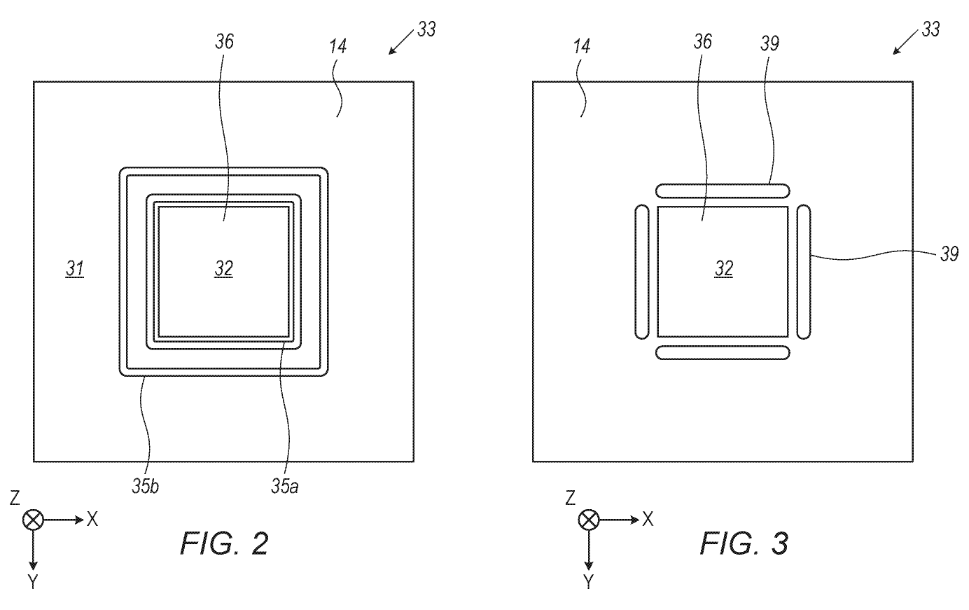

FIG. 2 is a schematic bottom view of lid 33 showing a first configuration of overflow channels 35a and 35b, in accordance with an embodiment that is described herein. In the present example, lid 33 is in a flipped position for showing surface 36 of section 32, and surface 14 of section 31 described in FIG. 1 above. In some embodiments, the amount of the liquid metal TIM 44 typically exceeds the capacity of the volume defined between surface 36 of protrusion 26 of lid 33, and upper surface 23 of IC die 22. In such embodiments, channels 35a and 35b surround protrusion 26 and are configured to provide a buffer volume to contain the overflow of liquid metal TIM 44. In the present configuration, inner overflow channel 35a and the outer overflow channel 35b are concentric with outer overflow channel 35b positioned outward from inner overflow channel 35a. Each of channels 35a and 35b is contiguous to enable flowing of the excess amount of LM TIM 44 all around protrusion 26.

In other embodiments, lid 33 may comprise any other suitable number of overflow channels 35, for example, a single channel 35a or three or more channels 35.

FIG. 3 is a schematic bottom view of lid 33 showing a second configuration of overflow channels 39, in accordance with another embodiment that is described herein. In some embodiments, lid 33 comprises four separate discrete overflow channels 39 positioned adjacent to four respective sides of section 32. As such, overflow containment channels 39 comprise four straight disconnected channels positioned on each side of protrusion 26. Each of channels 39 is configured to provide additional containment volume for excess liquid metal TIM 44 that overflows from the interface between IC die 22 and lower surface 36 of protrusion 26.

In other embodiments, lid 33 may comprise any other suitable number and shapes of channels to provide additional containment volume for excess liquid metal TIM 44. The channels may have multiple shapes arranged around protrusion 26 in any suitable configuration.

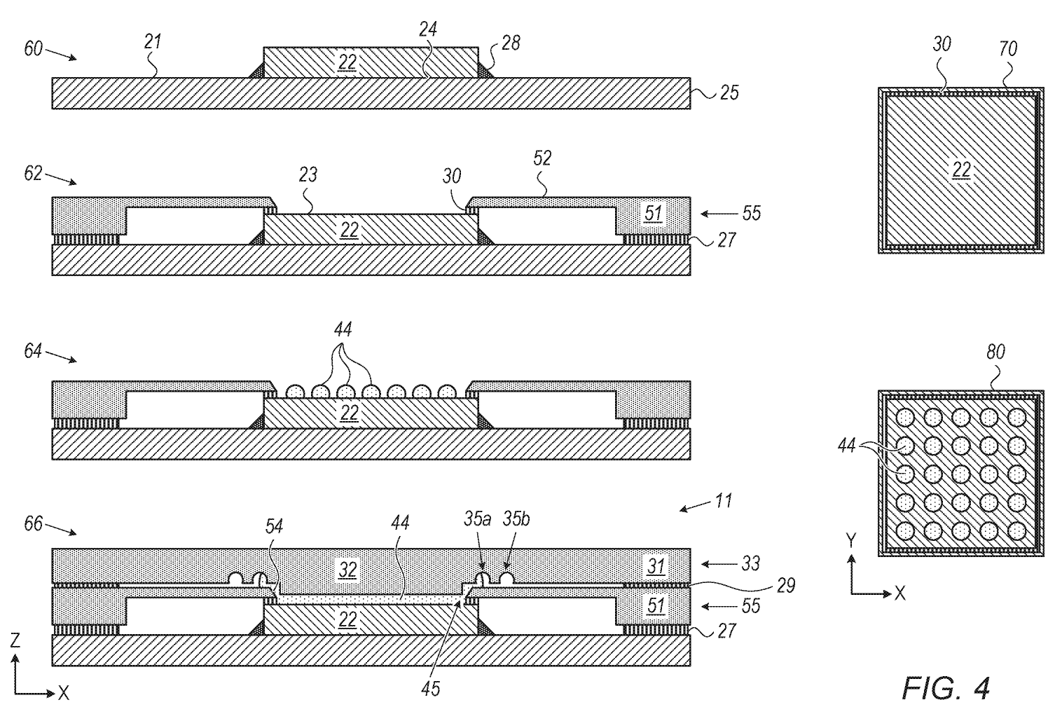

FIG. 4 is a series of cross-sectional views showing an assembly sequence of electronic device 11, in accordance with an embodiment that is described herein.

The assembly sequence, also referred to herein as a process, begins at a stage 60 with forming terminals 44 and disposing filling material 28 over surface 21 of substrate 25. Subsequently, IC die 22 is mounted over terminals 44 and filling material 28 to generate electrical coupling between IC die 22 and substrate 25. In this configuration substrate 25 and IC die 44 are configured to exchange electrical signals and electrical power and ground.

At a stage 62, adhesive layer 27 is disposed on surface 21 of substrate 25, and seal ring 30 is disposed over the edge of the upper surface 23 of IC die 22. Reference is now made to an inset 70, which shows a top view of IC die 22 with seal ring 30 disposed at the surrounding edge of the upper surface of IC die 22. Reference is now made back to the sectional view of stage 62. In some embodiments, stiffener 55 is positioned over adhesive layer 27 and seal ring 30.

At a stage 64, droplets of liquid metal TIM 44 are dispensed onto upper surface 23 of IC die 22. As described in FIGS. 1 and 2 above, the amount of liquid metal TIM 44 typically exceeds the capacity of the volume defined between surface 36 of protrusion 26, and upper surface 23 of IC die 22. A top view of the droplets of LM TIM 44 is shown in an inset 80. In other embodiments, liquid metal TIM 44 may be dispensed in various forms, such as jetting, stencil printing, or auger dispensing, and in different patterns such as but not limited to dotting, cross-hatch, and star patterns.

At a stage 66 that concludes the assembly sequence, adhesive layer 29 is disposed over surface 15 of section 51 of stiffener 55, and subsequently, lid 33 is placed on stiffener 55 with protrusion 26 displacing liquid metal TIM 44 to fill the volume between surface 36 of protrusion 26, and upper surface 23 of IC die 22. Moreover, in response to protrusion 26 displacing liquid metal TIM 44, the overflow of TIM 44 is directed through opening 45 into channel 35a (as shown) and into channel 35b in case the excess amount of TIM 44 exceeds the volume capacity within channel 35a. In some embodiments, one or more thermal cycles are applied to electronic device 11 to achieve hermetic sealing by adhesive layers 27 and 29, and seal ring 30, for protecting TIM 44 from humidity and oxidation and to prevent undesired spillage of TIM 44 toward surface 21 of substrate 25. In addition, in some embodiments, a gap (e.g., gap 16 in FIG. 1) may be at least partially filled with a sealing or gasketing material and/or may comprise one or more barrier layers (for example, a thin oxidation-based or nitride-based barrier), to further protect TIM 44 from oxidation.

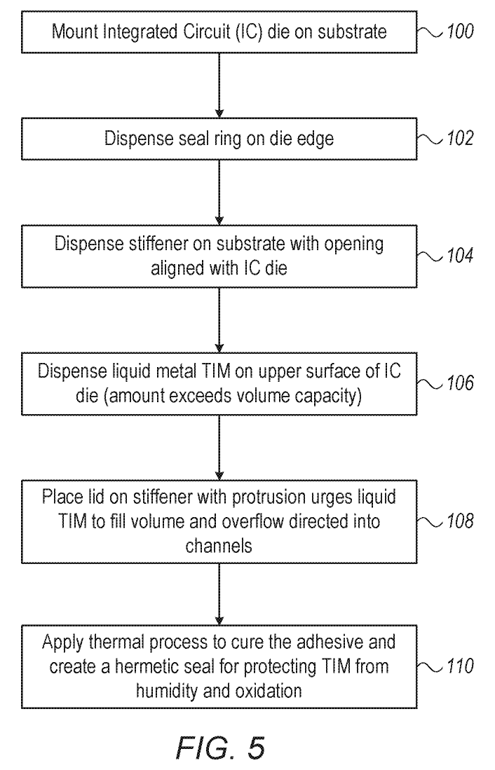

FIG. 5 is a flow chart that schematically illustrates a method for fabricating electronic device 11, in accordance with an embodiment that is described herein.

The method begins at an IC die mounting operation 100, with disposing IC die 22 and bumps 24 on substrate 25 and applying filling material 28 (i) between IC die 22 and laminate substrate 25, and (ii) at the edges of IC die 22, as described in FIG. 1 as well as in stage 60 of FIG. 4 above.

At a seal ring dispensing step 102, seal ring 30 is disposed on the edge of IC die 22 and adhesive layer 27 is dispensed over substrate 25, as described in detail in stage 62 of FIG. 4 above. In some embodiments, seal ring 30 is configured to isolate the volume (region) intended to contain TIM 44 from the substrate top surface. In such embodiments, after applying a thermal process (as described above) seal ring 30 is configured to provide a hermetic seal and protects the liquid metal TIM 44 from humidity and oxidation. In some embodiments, seal ring 30 comprises a thermally conductive adhesive material, which may be similar to that of adhesive layer 27.

At a stiffener disposing (e.g., mounting) step 104, stiffener 55 is mounted on substrate 25 with opening 12 aligned with at least a portion of IC die 22. Stiffener is attached with the seal adhesive of seal ring 30 configured to seal the volume intended to contain TIM 44 from being spilled over toward substrate 25, as described in detail in FIG. 1 and in stage 64 of FIG. 4 above. In some embodiments, opening 12 of stiffener 55 must be aligned with IC die 22 so that during testing and operations, sloped edge 54 could direct the overflow of liquid metal TIM 44 toward overflow containment channels 35a and 35b shown in FIGS. 1, 2 and 4 (or channels 39 shown in FIG. 3 above).

At a TIM dispensing step 106, liquid metal TIM 44 is dispensed on upper surface 23 of IC die 22, as described in detail in stage 64 of FIG. 4 above. The liquid metal of TIM 44 is dispensed according to a set of guidelines to ensure full coverage of surface 23 of die 22. In some embodiments, liquid metal TIM 44 is dispensed in an amount that exceeds the volume capacity between IC die 22 and protrusion 26 of lid 33. In other embodiments, other liquid metal-based TIM materials may be used, such as materials containing liquid metal in a carbon-based, metal-based, or elastomer-based matrix, which may exhibit similar requirements for containment and oxidation protection.

At a lid placing step 108, lid 33 is placed on stiffener 55. In some embodiments, lid 33 is placed and protrusion 26 displaces TIM 44 to cover IC die 22. Overflow liquid metal of TIM 44 is contained in the overflow channels 35a and 35b, as described in detail in FIGS. 1-3 and in stage 66 of FIG. 4 above.

At a hermetic sealing step 110 that concludes the method, a thermal process is applied to cure the adhesive material of layers 27 and 29 so as to form the aforementioned hermetic seal for protecting the liquid metal of TIM 44 from humidity and oxidation. The seal ring 30 provides a hermetic seal and protects the liquid metal from humidity and oxidation. In some embodiments, the hermetic seal by layers 27 and 29, in combination with seal ring 30, encapsulates the liquid metal of TIM 44 and protects liquid metal TIM 44 from environmental exposure.

It is noted that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An electronic device, comprising:
an integrated circuit (IC) die mounted on a substrate;
a stiffener disposed on the substrate, the stiffener comprising: (i) a bottom surface facing at least the substrate, and (ii) an opening aligned with at least part of the IC die;
a liquid metal thermal interface material (TIM) disposed on an upper surface of the IC die facing the opening; and
a lid disposed on the stiffener, the lid comprising:
a protrusion extending from a lower surface of the lid toward the IC die, wherein the protrusion is aligned with the opening and configured to contact the liquid metal TIM; and
one or more channels formed in the lower surface of the lid and shaped to at least partially surround the protrusion,
wherein, in response to placing the lid on the stiffener, the protrusion is configured to displace the liquid metal TIM to fill a volume defined between the lid and the upper surface of the IC die, and the one or more channels are configured to receive overflow of the liquid metal TIM from the volume.

2. The electronic device according to claim 1, wherein an edge of the stiffener defining the opening comprises a first surface facing the IC die and a second surface sloped and configured to direct the overflow of the liquid metal TIM from the volume toward the one or more channels.

3. The electronic device according to claim 2, further comprising a seal ring disposed between (i) the first surface at the edge of the stiffener, and (ii) a die edge at the upper surface of the IC die, wherein the seal ring is configured to laterally bound the liquid metal TIM within the volume.

4. The electronic device according to claim 3, wherein the seal ring comprises a thermally conductive adhesive.

5. The electronic device according to claim 1, wherein an amount of the liquid metal TIM exceeds a capacity of the volume defined between the lid and the upper surface of the IC die, and wherein the one or more channels provide a buffer volume to contain the overflow.

6. The electronic device according to claim 1, wherein the one or more channels comprise a first channel connected all around the protrusion.

7. The electronic device according to claim 6, wherein the one or more channels further comprise a second channel disposed outward of the first channel.

8. The electronic device according to claim 1, wherein the one or more channels comprise a plurality of discrete channels disposed adjacent to respective sides of the protrusion.

9. The electronic device according to claim 8, wherein the plurality of discrete channels comprises two parallel channels disposed adjacent to each side of the protrusion.

10. The electronic device according to claim 1, wherein the lid is configured to provide a hermetic seal to protect the liquid metal TIM from oxidation.

11. The electronic device according to claim 1, wherein the one or more channels are configured to contain residual liquid metal TIM, such that, in response to warping or flexing of the electronic device, the residual liquid metal TIM is configured to flow back into the volume.

12. The electronic device according to claim 1, wherein the protrusion is configured to reduce a thickness of the liquid metal TIM between the lid and the upper surface of the IC die.

13. A method for fabricating an electronic device, the method comprising:
mounting an integrated circuit (IC) die on a substrate;
disposing a stiffener on the substrate, the stiffener comprising: (i) a bottom surface facing at least the substrate, and (ii) an opening aligned with at least part of the IC die;
dispensing a liquid metal thermal interface material (TIM) on an upper surface of the IC die facing the opening; and
placing a lid on the stiffener, the lid comprising: (i) a protrusion extending from a lower surface of the lid toward the IC die, wherein the protrusion is aligned with the opening and configured to contact the liquid metal TIM, and (ii) one or more channels formed in the lower surface of the lid and shaped to at least partially surround the protrusion,
wherein placing the lid on the stiffener comprises displacing the liquid metal TIM via the protrusion to fill a volume defined between the lid and the upper surface of the IC die, and directing overflow of the liquid metal TIM from the volume into the one or more channels.

14. The method according to claim 13, wherein disposing the stiffener comprises disposing the stiffener having an edge defining the opening, the edge comprising a first surface facing the IC die and a second surface sloped to direct overflow of the liquid metal TIM from the volume toward the one or more channels.

15. The method according to claim 14, further comprising disposing a seal ring between (i) the first surface at the edge of the stiffener, and (ii) a die edge at the upper surface of the IC die, wherein the seal ring laterally bounds the liquid metal TIM within the volume.

16. The method according to claim 13, wherein dispensing the liquid metal TIM comprises dispensing an amount of the liquid metal TIM that exceeds a capacity of the volume defined between the lid and the upper surface of the IC die, and wherein the one or more channels provide a buffer volume to contain the overflow.

17. The method according to claim 13, wherein the one or more channels comprise a first channel connected all around the protrusion.

18. The method according to claim 17, wherein the one or more channels further comprise a second channel disposed outward of the first channel.

19. The method according to claim 13, wherein placing the lid on the stiffener retains residual liquid metal TIM in the one or more channels such that, in response to warping or flexing of the electronic device, the residual liquid metal TIM flows back into the volume.

20. An electronic device, comprising:
an integrated circuit (IC) die mounted on a substrate;
means for stiffening disposed on the substrate and having an opening aligned with at least part of the IC die;
a liquid metal thermal interface material (TIM) disposed on an upper surface of the IC die facing the opening; and
means for covering disposed on the means for stiffening, the means for covering comprising:
means for contacting extending toward the IC die, wherein the means for contacting is aligned with the opening and configured to contact the liquid metal TIM; and
means for containing overflow, shaped to at least partially surround the means for contacting,
wherein, in response to placing the means for covering on the means for stiffening, the means for contacting is configured to displace the liquid metal TIM to fill a volume defined between the means for covering and the upper surface of the IC die, and the means for containing overflow is configured to receive overflow of the liquid metal TIM from the volume.
